(19) United States
(12) Patent Application Publication
(10) Pub. No.: US 2008/0186047 A1
(43) Pub. Date: Aug. 7, 2008

(54) SYSTEM FOR SORTING PACKAGED CHIPS AND METHOD FOR SORTING PACKAGED CHIPS

(76) Inventors: Hee Rak Beom, Seoul-Si (KR); Dae Gon Yun, Gumi-Si (KR); Yong Geun Park, Asan-Si (KR)

Correspondence Address: KED & ASSOCIATES, LLP, P.O. Box 221200, Chantilly, VA, 20153-1200, US

(21) Appl. No.: 12/023,258

(22) Filed: Jan. 31, 2008

(30) Foreign Application Priority Data
Feb. 1, 2007 (KR) 10-2007-0010418

(51) Int. Cl. G01R 31/26

(52) U.S. Cl. 324/765

(57) ABSTRACT

Provided is a sorting system for handling packaged chips for testing and sorting the packaged chips by grade, capable of performing loading and unloading operations, independently of a testing operation. The sorting system includes a loading unit including a loading picker, an unloading unit provided adjacent to the loading unit, a rack in which to store at least one test tray containing the packaged chips intended for the tests and at least one test tray containing the tested packaged chips, an exchanging site where the test tray containing the packaged chips intended for the tests and the test tray containing the tested packaged chips are exchanged with the rack, and a transferring unit transferring the test tray between the loading position, the exchanging site, and the unloading position.

### BACKGROUND OF THE INVENTION

1. Field of the Invention

The present invention relates to a sorting system for handling packaged chips for testing and sorting the tested packaged chip by grade and a method for handling packaged chips for testing and sorting the tested packaged chip by grade.

2. Description of the Background Art

A handler puts packaged chips through an electrical test at the conclusion of a packaging process.

The handler transfers the packaged chips from a user tray to a test tray and supplies the test tray containing the packaged chips to an tester. The tester includes a test board with a plurality of sockets. The handler makes the packaged chips in the test tray individually contact with sockets of the test board. The tester then performs the electrical tests on the packaged chips. After sorting the packaged chips according to test results, the handler transfers them from the test tray to the corresponding user trays.

The handler includes first, second, and third chambers. In the first chamber, the packaged chips in the test tray are heated to extremely high temperature or cooled to extremely low temperature. In the second chamber, the packaged chips in the test tray receive the electrical test. In the third chamber, the packaged chips in the test tray are cooled or heated to room temperature. The packaged chips in the test tray go through the first, second, and third chambers in this order.

FIG. 1 is a plane view of a configuration for a conventional handler. FIG. 2 is a schematic view of a path which the test tray follows in the conventional handler of FIG. 1. Each of numeral characters in FIG. 2 indicates a component which is located along the path which the test tray follows in the conventional handler.

As shown FIGS. 1 and 2, the conventional handler 10 includes a chamber system 11 and a sorting system 12.

The chamber system 11 includes first, second, and third chambers 111, 112, and 113.

The packaged chips contained in the test tray are heated or cooled to testing temperature, while the test tray is moved forward inside the first chamber 111. To do this, an electric heat or an apparatus for injecting liquefied nitrogen is provided to the first chamber 11.

The packaged chips are made to individually contact sockets of the test board 1121 inside the second chamber 112 to receive the electrical tests (This is referred to as ‘testing operation’). A pushing unit 1122, pushing the test tray containing the packaged chips intended for the electrical tests toward the test board, is provided to the second chamber 112.

The packaged chips contained in the test tray are cooled or heated to room temperature while the test tray is moved forward inside the third chamber 113. To do this, an electric heater or an apparatus for injecting liquefied nitrogen is provided to the third chamber 113.

The chamber system 11 may further includes first and second transferring units 114 and 115. The first transferring unit 114 transfer the test tray containing the packaged chips intended for the electrical tests from the sorting system 12 to the first chamber 111. In addition, the first transferring unit 114 transfers the test tray containing the tested packaged chips from the third chamber 113 to the sorting system 12.

The second transferring unit 115 transfers the test tray containing the packaged chips intended for the electrical tests from the first chamber 111 to the second chamber 112. In addition, the second transferring unit 115 transfers the test tray containing the tested packaged chips from the second chamber 112 to the third chamber 113.

The sorting system 12 loads the packaged chips intended for the electrical tests into the test tray (This is referred to as ‘loading operation’) and unloads the tested packaged chips from the test tray (This is referred to as ‘unloading operation’)

The sorting system 12 includes a loading stacker 121, an unloading stacker 122, a first picker 123, a second picker 124, a buffer unit 125, an exchanging site 126, and a rotating unit 127.

Two or more user trays, each containing the packaged chips intended for the electrical tests, stay in the loading stacker 121.

The two or more user trays, each containing the tested packaged chips, stay in the unloading stacker 122. The tested packaged chip, after sorted by grade, is loaded into the corresponding user tray staying in the unloading stacker 122.

The first picker 123, movable in the X-axis and Y-axis directions as shown in FIG. 1, includes nozzles. The picker picks up the packaged chips by sucking air into each nozzle. The handler 10 includes the two or more first pickers 123.

At least one first picker 123 picks up the packaged chips intended for the electrical tests from the user tray staying in the loading stacker 121 and places them on the buffer unit 125.

Each of the other first pickers 123 picks up the tested packaged chips from the buffer unit 125, sorts them by grade, and places them into the corresponding user trays staying in the unloading stacker 122.

The second picker 124, movable in the X-axis direction as shown in FIG. 1, includes nozzles. The picker picks up the packaged chips by sucking air into each nozzle. The handler 10 includes the two or more second pickers 124.

At least one second picker 124 picks up the packaged chips intended for the electrical tests, from the buffer unit 125 and places them into the test tray staying in the exchanging site 126.

Each of the other second pickers 124 picks up the tested packaged chips from the test tray staying in the exchanging site 126 and places them on the buffer unit 125.

The packaged chips are temporarily placed on the buffer unit 125, movable in the Y-axis direction as shown in FIG. 1. The handler 10 includes the two or more buffer units 125.

Among the buffer units 125, the packaged chips intended for the electrical tests are temporarily placed on the buffer unit 125 which is positioned adjacent to one side of the exchanging site 126.

The tested packaged chips are temporarily placed on the buffer unit 125 which is positioned adjacent to the opposite side of the exchanging site 126.

The exchanging site 126 is where the test tray containing the tested packaged chips and the test tray containing the packaged chips intended for the electrical tests are exchanged with each other.

By way of the exchanging site 126, the test tray containing the packaged chips intended for the electrical tests is transferred from the sorting system 12 to the chamber system 11. By way of the exchanging site 126, the test tray containing the tested packaged chips is transferred from the chamber system 11 to the sorting system 12.

In the exchanging site 126, the tested packaged chips are unloaded from the test tray and the packaged chips intended for the electrical tests are loaded into the test tray.

The rotating unit 127 is provided to the exchanging site 126. The rotating unit 27 rotates the test tray containing the packaged chips intended for the electrical tests, from the horizontal position to the upright position, and the test tray containing the tested packaged chips, from the upright position to the horizontal position.

However, the conventional handler performs both of the testing operation and the unloading operation. Thus, the conventional handler cannot perform the unloading operation before finishing the testing operation. This places a major limitation to increasing the speed of testing the packaged chips.

Furthermore, the conventional handler 10 places the packaged chips intended for the electrical tests into a carrier of the test tray at the exchanging site 126 where the tested packaged chip was unloaded from the carrier. That is, in the conventional handler 10, the loading operation and the unloading operation are performed at the same location. Thus, the speed of testing the packaged chips has a considerable impact on the loading operation.

A malfunction of a main component such as the picker during one operation stops the other operation.

Inclusion of the sorting system 12 in the handler 10 increases the number and complexity of components of the handler 10, leading to frequent occurrence of malfunctions.

### BRIEF DESCRIPTION OF THE INVENTION

Therefore, an object of the present invention is to provide a sorting system for handling packaged chips for testing and sorting the packaged chips by grade, capable of performing loading and unloading operations, independently of a testing operation and a method for handling packaged chips for testing and sorting the packaged chips by grade, in which loading and unloading operations are performed independently of a testing operation.

Another object of the present invention is a sorting system for handling packaged chips for testing and sorting the packaged chips by grade, capable of reducing the number and complexity of components of a handler and a method for handling packaged chips for testing and sorting the packaged chips by grade, in which the number and complexity of components of a handler is reduced.

According to an aspect of the present invention, there is provided a sorting system for handling packaged chips for testing and sorting the packaged chips by grade, the sorting system including a loading unit including a loading picker picking up packaged chips intended for tests from a user tray and placing them into a test tray staying at a loading position, an unloading unit, provided adjacent to the loading unit, picking up tested packaged chips from a test tray staying at an unloading position and sorting them by grade, a rack in which to store at least one test tray containing the packaged chips intended for the tests and at least one test tray containing the tested packaged chips, an exchanging site, provided between the loading unit and the unloading unit, where the test tray containing the packaged chips intended for the tests and the test tray containing the tested packaged chips are exchanged with the rack, and a transferring unit transferring the test tray between the loading position, the exchanging site, and the unloading position.

According to another aspect of the present invention, there is provided a method for handling packaged chips for testing and sorting the packaged chips by grade, the method including steps of transferring a test tray containing tested packaged chips from an exchanging site to an unloading position, unloading the tested packaged chips from the test tray staying at the unloading position, transferring the test tray from which the tested packaged chips are unloaded, from the unloading position to a loading position, loading packaged chips intended for tests into a test tray staying at the loading position, transferring the test tray into which the packaged chips intended for the tests are loaded, from the loading position to the exchanging site, transferring the test tray containing the packaged chips intended for the tests from the exchanging site to a first rack, and transferring the test tray containing the tested packaged chips from a second rack to the exchanging site.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a plane view of a configuration for a conventional handler;

FIG. 2 is a schematic view of a path which the test tray follows in the conventional handler of FIG. 1;

FIG. 3 is a plane view illustrating a sorting system according to the present invention;

FIG. 4 is a schematic view illustrating a path which the test tray follows in the sorting system according to a first embodiment of the present invention; and

FIG. 5 is a schematic view illustrating a path which the test tray follows in the sorting system according to a second embodiment of the present invention

### DETAILED DESCRIPTION OF THE INVENTION

Reference will now be made in detail to embodiments of the present invention, examples of which are illustrated in the accompanying drawings.

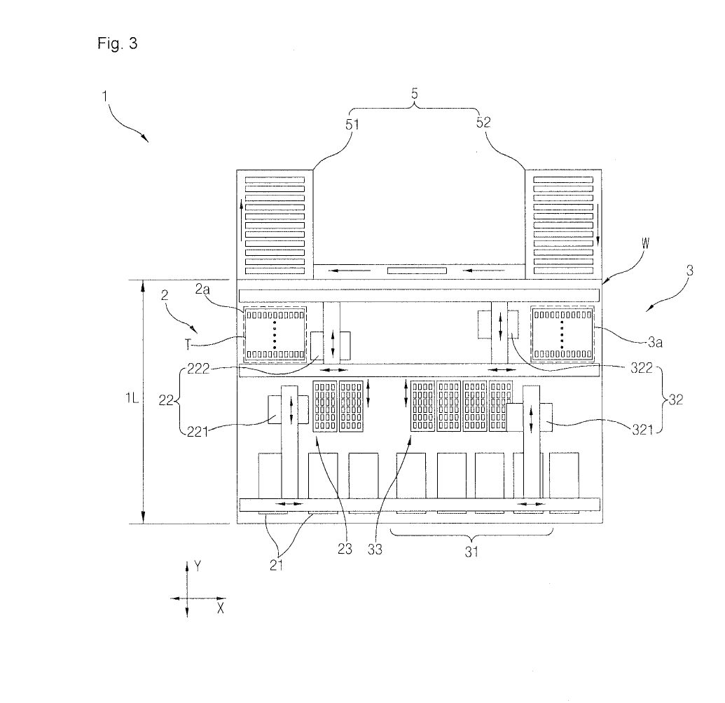

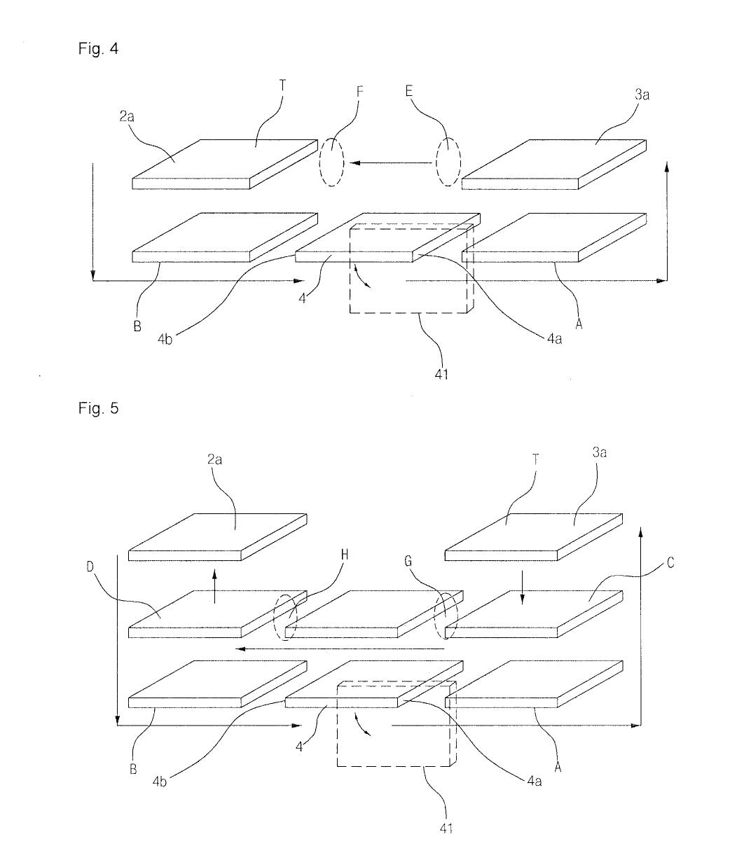

FIG. 3 is a plane view illustrating a sorting system according to the present invention. FIG. 4 is a schematic view illustrating a path which the test tray follows in the sorting system according to a first embodiment of the present invention.

As shown in FIGS. 3 and 4, the sorting system 1 according to the present invention includes a loading unit 2, an unloading unit 3, an exchanging site 4, a rack 5 and a transferring unit (not shown).

The loading unit 2 performs a loading operation. The loading unit 2 includes a loading stacker 21, a loading picker 22, and a loading buffer 23.

In a loading stacker 21, a user tray containing packaged chips intended for electrical tests stays.

The loading picker 22, movable in the X-axis and Y-axis directions (as shown in FIG. 3), includes nozzles. The loading picker 22 picks up the packaged chips by sucking air into each nozzle. The loading picker 22 includes a first loading picker 221 and a second loading picker 222.

The first loading picker 221 picks up the packaged chips intended for the electrical tests from the user tray staying in the loading stacker 21 and places them on the loading buffer 23. The sorting system 1 may include the two or more first loading pickers 221.

The second loading picker 222 picks up the packaged chips intended for the electrical tests from the loading buffer 23 and places them into a test tray T staying at a loading position 2a. The sorting system 1 may include the two or more second loading pickers 222.

The packaged chips intended for the electrical tests are temporarily placed on the loading buffer 23, movable in the Y-axis direction, as shown in FIG. 3. The sorting system 1 may include the two or more loading buffers 23.

The unloading unit 3 performs an unloading operation. As shown in FIGS. 3 and 4, the unloading unit 3 is provided adjacent to the loading unit 2. The unloading unit 3 includes an unloading stacker 31, an unloading picker 32 and an unloading buffer 33.

The two or more user tray, each containing the tested packaged chips, stay in the unloading stacker 31. The tested packaged chips, after sorted by grade, are placed into the corresponding user trays.

The unloading picker 32, movable in the X-axis and Y-axis directions as shown in FIG. 3) includes nozzles. The unloading picker 32 picks up the packaged chips by sucking air into each nozzle. The unloading picker 32 includes first and second unloading pickers 321 and 322.

The first unloading picker 321 picks up the tested packaged chips from the unloading buffer 33 and places them into the user tray staying in the unloading stacker 31. The sorting system 1 may include the two or more first unloading pickers 321.

The second unloading picker 322 picks up the tested packaged chips from the test tray T staying at an unloading position 3a and places them on the unloading buffer 33. The sorting system 1 may include the two or more second loading pickers 322.

The tested packaged chips are temporarily placed on the unloading buffer 33, movable in the Y-axis direction (as shown in FIG. 3). The sorting system 1 may include the two or more unloading buffers 33.

In the sorting system 1, the loading operation and the unloading operation are individually performed at different locations. That is, the packaged chips can be loaded into the test tray staying at the loading position 2a, independently of the unloading operation, thus increasing productivity.

As shown in FIGS. 3 and 4, the exchanging site 4 is provided between the loading unit 2 and the unloading unit 3.

In the exchanging site 4, the test tray T containing the packaged chips intended for the electrical tests and the test tray T containing the tested packaged chips are exchanged with the rack 5.

The transferring unit (now shown) is provided to the exchanging site 4. The transferring unit transfers the test tray T containing the packaged chips intended for the electrical tests from the exchanging site 4 to the rack 5, and the test tray T containing the tested packaged chips from the rack 5 to the exchanging site 4.

The transferring unit may include a drive pulley, a driven pulley, a belt connecting between the drive and driven pulleys, a motor driving the drive pulley and a moving part pushing or pulling the test tray T, which are all not shown.

A rotating unit 41, rotating the test tray T, may be further provided to the exchanging site 4.

The rotating unit 41 rotates the horizontally-positioned test tray T containing the packaged chips intended for the electrical tests to make it in the upright position. The rotating unit 41 rotates the upright-positioned test tray T containing the tested packaged chips to make it in the horizontal position.

The sorting system 1 loads and unloads the packaged chips into and from the horizontally-positioned test tray T, respectively, and transfers the upright-positioned test tray T to the rack 5.

As shown in FIG. 3, the rack 5 stores at least one test tray T containing the packaged chips intended for the electrical tests and at least one test tray T containing the tested packaged chips.

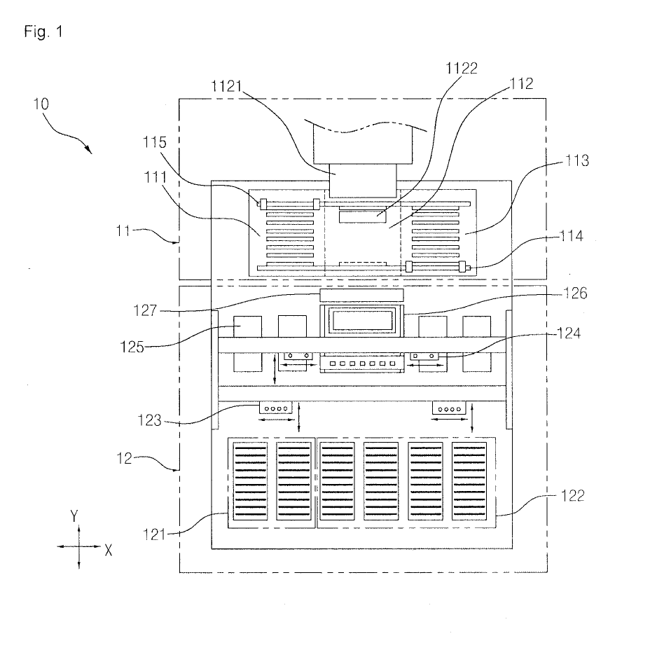

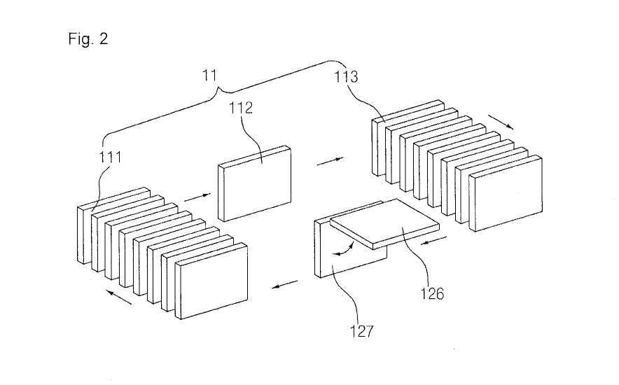

Existence of the rack 5 makes the sorting system 1 functionally separable from the chamber system 11 (as shown in FIG. 1).

The test tray T containing the tested packaged chips, stored in the rack 5, is to be transferred to the sorting system 1 by way of the chamber system. The test tray T containing the packaged chips intended for the electrical tests, stored in the rack 5 is to be transferred to the chamber system by way of the sorting system.

Thus, the sorting system 1 performs the unloading and loading operations, regardless of how long it takes to perform the electrical tests on the packaged chips contained in the upright-positioned inside the chamber system.

Normally, it takes more time to perform the electrical test than it does to perform the loading or unloading operation. So, the two or more chamber systems may be provided to the single sorting system 1.

The rack 5 may include a first rack 51 and a second rack 52.

The first rack 51 is detachably provided to a main body W of the sorting system 1. The first rack 51 stored at least one test tray T containing the packaged chips intended for the electrical tests. The first rack 51 may be detachably provided to the chamber system.

The first rack 51 may be manually or automatically separated from the sorting system 1 and then connected to the chamber system, when having a given number of the test tray T, containing the packaged chips intended for the electrical tests, which is transferred by way of the sorting system 1.

The packaged chips intended for the electrical tests, contained in the test tray T, can be heated or cooled to testing temperature inside the first rack 51. The first rack 51 may include an airtight chamber and an electric heater or an apparatus for injecting liquefied nitrogen. The test tray T can be moved forward inside the first rack 51.

Thus, in a case where the first rack 51 is connected to the chamber system, the test tray T containing the packaged chips intended for the electrical tests can be transferred to the second chamber 112 as shown in FIG. 1 without passing through the first chamber 111 as shown in FIG. 1.

The second rack 52 is detachably provided to the main body of the sorting system 1. The second rack 52 stores at least one test tray T containing the tested packaged chips. The second rack 52 may be detachably provided to the chamber system.

The second rack 52 may be manually or automatically separated from the chamber system and then be connected to the sorting system 1, when having a given number of the test tray T, containing the tested packaged chips, which is transferred by way of the chamber system.

The second rack 52 may be manually or automatically separated from the sorting system 1 and then be connected to the chamber system, when the test trays T, each containing the tested packaged chips, are all transferred to the sorting system 1.

The tested packaged chips, contained in the test tray T, can be cooled or heated to room temperature inside the second rack 52. The second rack 52 may include an airtight chamber and an electric heater or an apparatus for injecting liquefied nitrogen. The test tray T can be moved forward inside the second rack 52.

Thus, in a case where the second rack 51 is connected to the chamber system, the test tray T containing the tested packaged chips can be transferred to the second rack 52 from the second chamber 112 as shown in FIG. 1 without passing through the third chamber 113 as shown in FIG. 1.

As shown in FIGS. 3 and 4, the transferring unit transfers the test tray T, from the loading position 2a to the exchanging site 4, from the unloading position 3a to the loading position 2a, and from the exchanging site 4 to the unloading position 3a.

The transferring unit may include a drive pulley, a driven pulley, a belt connecting between the drive and driven pulleys, a motor driving the drive pulley and a moving part pushing or pulling the test tray T, which are all not shown.

The transferring unit may include first and second transferring units (not shown)

The first transferring unit transfers the test tray T containing the tested packaged chips from the exchanging site 4 to the unloading position 3a, by way of a first waiting position A.

The first waiting position A is where the test tray T containing the tested packaged chips waits to be transferred to the unloading position 3a. The first waiting position A may be located adjacent to one side 4a of the exchanging site 4.

The first waiting position A may be located to be in a horizontal line with the exchanging site 4 and the unloading position 3a (This is not shown). Thus, the first transferring unit can horizontally transfers the test tray T containing the tested packaged chips from the exchanging site 4 to the unloading position 3A, by way of the first waiting position A.

The first waiting position A, as shown in FIG. 4, may be located to be in a horizontal line with the exchanging site 4 and below the unloading position 3a. In this case, the first transferring unit may include a first ascending/descending unit ascending to move upward the test tray containing the tested packaged chips from the first waiting position A to the unloading position 3a.

As shown in FIG. 4, the test tray T containing the tested packaged chips can be horizontally transferred from the exchanging site 4 to the first waiting position A and be moved upward from the first waiting position A to the unloading position 3a.

The second transferring unit transfers the test tray T containing the packaged chips intended for the electrical tests from the loading position 2a to the exchanging site 4, by way of the second waiting position B.

The second waiting position B is where the test tray T containing the packaged chips intended for the electrical tests waits to be transferred to the exchanging site 4. The second waiting position B may be adjacent to the opposite side 4b of the exchanging site 4.

The second waiting position B may be located to be in a horizontal line with the loading position 2a, and the exchanging site 4 (This is not shown). In this case, the second transferring unit can horizontally transfer the test tray T containing the packaged chips intended for the electrical tests from the loading position 2a to the exchanging site 4, by way of the second waiting position B.

The second waiting position B, as shown in FIG. 4, is located to be in a horizontal line with the exchanging site 4 and below the loading position 2a. In this case, the second transferring unit may include a second ascending/descending unit descending to move downward the test tray T containing the tested packaged chips from the loading position 2a to the second waiting position B.

As shown in FIG. 4, the test tray T containing the packaged chips intended for the electrical tests can be moved downward from the loading position 2a to the second waiting position B and be moved horizontally from the second waiting position B to the exchanging site 4.

The first and second waiting positions A and B and the exchanging site 4 may be located to be in a horizontal line. The loading and unloading positions 2a and 3a may be located to be in a horizontal and to be above the first and second waiting positions A and B. This is done to reduce a length 1L of the sorting system 1 as shown in FIG. 3.

As shown in FIGS. 3 and 4, the transferring unit may include a third transferring unit (not shown). The third transferring unit transfers the test tray T from which the tested packaged chips are unloaded, from the unloading position 3a to the loading position 2a.

The loading buffer 23 and the unloading buffer 33 may be moved to get out of a path which the test tray T, from which the tested packaged chips are unloaded, follows, before the third transferring unit transfers it from the unloading position 3a to the loading position 2a.

The loading buffer 23 and unloading buffer 33 may not be located between the loading and unloading positions 2a and 3a. For example, the loading buffer 23 may be located to the left of the loading position 2a and the unloading buffer 33 to the right of the unloading position 3a.

As shown in FIG. 4. the sorting system 1 may further include a detecting unit (not shown)

The detecting unit detects if the packaged chips remains in the test tray T after the unloading operation. This is done to prevent the packaged chips intended for the electrical tests from being loaded into the test tray T containing the tested packaged chip. The detecting unit may include a light sensor.

The detecting unit detects if the tested packaged chip remains in the test tray T which is to be transferred from the unloading position 3A to the loading position 2A. The detecting unit may be provided around an exit E of the unloading position 3a or an entrance F of the loading position 2a.

A second embodiment of the present invention is now described. What distinguishes the second embodiment from the first embodiment is described to maintain consistency in explanation.

FIG. 5 is a schematic view illustrating a path which the test tray T follows in a sorting system according to the second embodiment of the present invention.

As shown in FIGS. 3 and 5, the sorting system 1 according to the second embodiment of the present invention includes a transferring unit (not shown), in addition to the above-described elements of the first embodiment.

The first transferring unit transfers the test tray T containing the tested packaged chips from the exchanging site 4 to the unloading position 3a, by way of the first waiting position A.

The first waiting position A is where the test tray T containing the tested packaged chips waits to be transferred to the unloading position 3a. The first waiting position A may be located around one side 4a of the exchanging site 4.

The first waiting position A, as shown in FIG. 5, may be located to be in a horizontal line with the exchanging site 4 and to be below the unloading position 3a. A third waiting position C may be located between the first waiting position A and the unloading position 3a. The third waiting position C is where the test tray T, from which the tested packaged chips are unloaded, waits to be transferred to the loading position 2a.

The first transferring unit includes a first ascending/descending unit (not shown) to transfer the test tray T from the first waiting position A to the unloading position 3a, and from the unloading position 3a to the third waiting position C.

The first ascending/descending unit ascends to move upward the test tray T containing the tested packaged chips from the first waiting position A to the unloading position 3a. The tested packaged chips are unloaded from the test tray T staying at the unloading position 3a.

The first ascending/descending unit descends to move downward the test tray T from which the tested packaged chips are unloaded, from the unloading position 3a to the third waiting position C.

The second transferring unit transfers the test tray T containing the packaged chips intended for the electrical tests from the loading position 2a to the exchanging site 4, by way of the second waiting position B.

The second waiting position B is where the test tray T containing the packaged chips intended for the electrical tests waits to be transferred to the exchanging site 4. The second waiting position B is located adjacent to the opposite side 4b of the exchanging site 4.

The second waiting position B, as shown in FIG. 5, is located to be in a horizontal line with the exchanging site 4 and to be below the loading position 2a. A fourth waiting position D may be located between the second waiting position B and the loading position 2a. The fourth waiting position D is where the test tray, from which the packaged chips are unloaded, waits to be transferred to the loading position 2a.

The second transferring unit includes a second ascending/descending unit (not shown) to transfer the test tray T from the fourth waiting position D to the loading position 2a, and from the loading position 2a to the second waiting position B.

The second ascending/descending unit ascends to move upward the test tray T from which the tested packaged chips are unloaded, from the fourth waiting position D to the loading position 2a. The packaged chips intended for the electrical tests are loaded into the test tray T staying at the loading position 2a.

The second ascending/descending unit descends to move downward the test tray containing the packaged chips intended for the electrical tests, from the loading position 2a to the second waiting position B.

The third transferring unit transfers the test tray, from which the packaged chips are unloaded, from the third waiting position C to the fourth waiting position D.

The third and fourth waiting positions C and D are located to be in a horizontal line. Thus, the third transferring unit can move horizontally the test tray T, from which the packaged chips are unloaded. The unloading position 3a is located above the third waiting position C. The first waiting position A is located below the third waiting position C. The loading position 2a is located above the fourth waiting position D. The second waiting position B is located below the fourth waiting position D.

The third transferring unit transfers the test tray T from the third waiting position C to the fourth waiting position D, below the unloading position 3a and the loading position 2a. Thus, the loading buffer 23 and the unloading buffer 33 can be located between the unloading position 3a and the loading position 2a. Furthermore, during transfer of the test tray T from the third waiting position C and the fourth waiting position D, the packaged chips intended for the electrical tests can be placed on the loading buffer 23 and the tested packaged chips can be unloaded from the unloading buffer 33.

The detecting unit detects if the packaged chip remains in the test tray T which is to be transferred from the third waiting position C to the fourth waiting position D. The detecting unit may be provided around an exit G of the third waiting position C or around an entrance H of the fourth waiting position D.

A method for handling packaged chips for testing and sorting the tested packaged chip by grade are now described.

The test tray T containing the tested packaged chips is transferred by the first transferring unit from the exchanging site 4 to the unloading position 3a (the first step)

The packaged chips are unloaded from the test tray staying at the unloading position 3a (the second step).

In the second step, the unloading picker 32 picks up the tested packaged chips from the test tray T staying at the unloading position 3a and places them on the unloading buffer 33. And the unloading picker 32 picks up the tested packaged chips from the unloading buffer 33 and places them into the user tray staying in the unloading stacker 31. At this point, the tested packaged chip, after sorted by grade, is placed into the corresponding user tray.

The test tray T, from which the packaged chips are unloaded, is transferred by the third transferring unit from the unloading position 3a to the loading position 2a (the third step).

The packaged chips intended for the electrical tests are loaded into the test tray T staying at the loading position 2a (the fourth step).

In the fourth step, the loading picker 23 picks up the packaged chips intended for the electrical tests from the user tray staying at the loading stacker 21 and places them on the loading buffer 23. And the loading picker 23 picks up the packaged chips intended for the electrical tests from the loading buffer 23 and places them into the test tray T staying at the loading position 2a.

The test tray T containing the packaged chips intended for the electrical tests is transferred by the second transferring unit from the loading position 2a to the exchanging site 4 (the fifth step).

The test tray T containing the packaged chips intended for the electrical tests is transferred by a transferring unit provided to the exchanging site 4, from the exchanging site 4 to the first rack 51 (the sixth step)

The rotating unit 41 may be provided to the exchanging site 4. The rotating unit 41 rotates the test tray T containing the packaged chips intended for the electrical tests to make it in the upright position. Subsequently, the transferring unit transfers the upright-positioned test tray T from the exchanging site 4 to the first rack 51.

The test tray T containing the tested packaged chips is transferred by a transferring unit, from the second rack 52 to the exchanging site 4 (the seventh step).

The rotating unit 41 may be provided to the exchanging site 4. The upright-positioned test tray T containing the tested packaged chips is transferred by the transferring unit from the second rack 52 to the exchanging site 4. Subsequently, the rotating unit 41 rotates the upright-positioned test tray T containing the tested packaged chips to make it in the horizontal position

The sixth and seventh steps may be performed at the same time. That is, the transferring unit, provided to the exchanging site 4, may begin to transfer the test tray T containing the packaged chips intended for the electrical tests and at the same time may begin to transfer the test tray T containing the tested packaged chips.

The method for handling packaged chips for testing and sorting the tested packaged chip by grade may further include a following eighth step. In the first step, the test tray T containing the tested packaged chips is transferred from the exchanging site 4 to the unloading position 3a, by way of the first waiting position A (the eighth step).

In the eighth step, the first transferring unit transfers horizontally the test tray T containing the tested packaged chips from the exchanging site 4 to the first waiting position A and subsequently the first ascending/descending unit ascends to move upward it from the first waiting position A to the unloading position 3a.

In this case, the first waiting position A may be located to be in a horizontal line with the exchanging site 4. And the first waiting position A may be located around one side 4a of the exchanging site 4 and below the unloading position 3a.

The eighth and third steps may be performed at the same time. The third transferring unit may begin to transfer the test tray T, from which the packaged chips are all unloaded, and at the same time the first transferring unit may begin to transfer the test tray T containing the tested packaged chips. This makes it possible to reduce the waiting time for the test tray T containing the tested packaged chips, resulting in reducing the time for the unloading operation.

In the fifth step, the test tray T into which to load the packaged chip intended for the electrical tests is transferred from the loading position 2a to the exchanging site 4, by way of the second waiting position B (the ninth step).

In the ninth step, the second ascending/descending unit descend to move downward the test tray T containing the packaged chips intended for the electrical tests from the loading position 2a to the second waiting position B, and subsequently the second transferring unit transfers horizontally the test tray T containing the packaged chips intended for the electrical tests from the second waiting position B to the exchanging site 4. In this case, the second waiting position B may be located to be in a horizontal line with the exchanging site 4. And the second waiting position B may be located around the opposite side 4b of the exchanging site 4 and below the loading position 2a.

The ninth and third steps may be performed at the same time. That is, the second transferring unit may begin to transfer the test tray T containing the packaged chips intended for the electrical testes, and at the same time the third transferring unit may begin to transfer the test tray T, from which the tested packaged chips are unloaded.

The method for handling packaged chips for testing and sorting the tested packaged chip by grade reduces the waiting time for the test tray T from which the tested packaged chip are unloaded, thus reducing the time for the loading operation.

The third step may further include a following tenth step. The test tray T, from which the tested packaged chips are unloaded, is transferred from the unloading position 3a to the third waiting position C (the tenth step).

In the tenth step, the first ascending/descending unit may descend to move downward the test tray T from which the packaged chips are unloaded, from the unloading position 3a to the third waiting position C. In this case, the third waiting position C may be located below the unloading position 3a and above the first waiting position A.

Next, the test tray T staying at the third waiting position C is transferred from the third waiting position C to the fourth waiting position D (the eleventh step).

In the eleventh step, the third transferring unit may horizontally transfer the test tray T staying at the third waiting position C from the third waiting position C to the fourth waiting position D. In this case, the third and fourth waiting positions C and D may be located to be in a horizontal line.

Next, the test tray T staying at the fourth waiting position D is transferred from the fourth waiting position D to the loading position 2a (the twelfth step)

In the twelfth step, the second ascending/descending unit ascends to move upward the test tray T staying at the fourth waiting position D from the fourth waiting position D to the loading position 2a. In this case, the fourth waiting position D may be located below the loading position 2a and above the second waiting position B.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. A sorting system for handling packaged chips for testing and sorting the packaged chips by grade, comprising:
a loading unit including a loading picker picking up packaged chips intended for tests from a user tray and placing them into a test tray staying at a loading position;
an unloading unit, provided adjacent to the loading unit, picking up tested packaged chips from a test tray staying at an unloading position and sorting them by grade;
a rack in which to store at least one test tray containing the packaged chips intended for the tests and at least one test tray containing the tested packaged chips;
an exchanging site, provided between the loading unit and the unloading unit, where the test tray containing the packaged chips intended for the tests and the test tray containing the tested packaged chips are exchanged with the rack; and
a transferring unit transferring the test tray between the loading position, the exchanging site, and the unloading position.

2. The sorting system for handling packaged chips for testing and sorting the packaged chips by grade, according to claim 1, wherein the transferring unit comprises:
a first transferring unit for transferring the test tray containing the tested packaged chips from the exchanging site to the unloading position, by way of a first waiting position;
a second transferring unit for transferring the test tray containing the packaged chips intended for the tests, from the loading position to the exchanging site, by way of a second waiting position; and
a third transferring unit for transferring the test tray, from which the tested packaged chips are unloaded, from the unloading position to the loading position.

3. The sorting system for handling packaged chips for testing and sorting the packaged chips by grade, according to claim 2,
wherein the first transferring unit comprises a first ascending/descending unit ascending to move upward the test tray containing the tested packaged chip from the first waiting position to the unloading position, and
wherein the second transferring unit comprises a second ascending/descending unit descending to move downward the test tray containing the packaged chip intended for the tests from the loading position to the second waiting position.

4. The sorting system for handling packaged chips for testing and sorting the packaged chips by grade, according to claim 1, wherein the transferring unit comprises:
a first transferring unit for transferring the test tray containing the tested packaged chips from the exchanging site to the unloading position, by way of a first waiting position;
a second transferring unit for transferring the test tray containing the packaged chips intended for the tests, from the loading position to the exchanging site, by way of a second waiting position; and
a third transferring unit for transferring the test tray, from which the tested packaged chips are unloaded, from a third waiting position to a fourth waiting position.

5. The sorting system for handling packaged chips for testing and sorting the packaged chips by grade, according to claim 4,
wherein the first transferring unit comprises a first ascending/descending unit ascending to move upward the test tray containing the tested packaged chips from the first waiting position to the unloading position and descending to move downward the test tray from which the tested packaged chips are unloaded, from the unloading position to the third waiting position, and
wherein the second transferring unit comprises a second ascending/descending unit ascending to move upward the test tray from which the tested packaged chips are unloaded, from the fourth waiting position to the loading position and descending to move downward the test tray containing the packaged chips intended for the tests from the loading position to the second waiting position.

6. The sorting system for handling packaged chips for testing and sorting the packaged chips by grade, according to claim 1, further comprising a detecting unit, provided between the unloading position and the loading position, detecting if the packaged chip remains in the test tray after the unloading operation.

7. The sorting system for handling packaged chips for testing and sorting the packaged chips by grade, according to claim 1, wherein a rotating unit, rotating the test tray, is provided to the exchanging site.

8. The sorting system for handling packaged chips for testing and sorting the packaged chips by grade, according to claim 1, wherein the rack comprises:
a first rack, is detachably provided to a main body, storing at least one test tray containing the packaged chips intended for the test; and
a second rack, is detachably provided to a main body, storing at least one test tray containing the tested packaged chips.

9. The sorting system for handling packaged chips for testing and sorting the packaged chips by grade, according to claim 8,
wherein the packaged chips intended for the tests contained in the test tray are heated or cooled to testing temperature inside the first rack, and
wherein the tested packaged chips contained in the test tray are cooled or heated to room temperature inside the second rack.

10. A method for handling packaged chips for testing and sorting the packaged chips by grade, comprising steps of:
transferring a test tray containing tested packaged chips from an exchanging site to an unloading position;
unloading the tested packaged chips from the test tray staying at the unloading position;
transferring the test tray from which the tested packaged chips are unloaded, from the unloading position to a loading position;
loading packaged chips intended for tests into a test tray staying at the loading position;
transferring the test tray containing the packaged chips intended for the tests, from the loading position to the exchanging site;
transferring the test tray containing the packaged chips intended for the tests from the exchanging site to a first rack; and
transferring the test tray containing the tested packaged chips from a second rack to the exchanging site.

11. The method for handling packaged chips for testing and sorting the packaged chips by grade, according to claim 10, wherein the step of transferring a test tray containing tested packaged chips from an exchanging site to an unloading position further comprises a step of transferring the test tray containing the tested packaged chips from the exchanging site to the unloading position by way of a first waiting position, which is performed at the same time with the step of transferring the test tray from which the tested packaged chips are unloaded, from the unloading position to a loading position.

12. The method for handling packaged chips for testing and sorting the packaged chips by grade, according to claim 10, wherein the step of transferring the test tray containing the packaged chips intended for the tests from the exchanging site to the first rack is performed at the same time with the step of transferring the test tray containing the tested packaged chips from the second rack to the exchanging site.

13. The method for handling packaged chips for testing and sorting the packaged chips by grade, according to claim 10, wherein the step of transferring the test tray containing the packaged chips intended for the tests, from the loading position to the exchanging site further comprises a step of transferring the test tray into which the packaged chips are loaded, from the loading position to the exchanging site by way of a second waiting position, which is performed at the same time with the step of transferring the test tray from which the tested packaged chips are unloaded, from the unloading position to a loading position.

14. The method for handling packaged chips for testing and sorting the packaged chips by grade, according to claim 10, wherein the step of transferring the test tray from which the tested packaged chips are unloaded, from the unloading position to a loading position further comprises steps of:
transferring the test tray from which the tested packaged chips are unloaded, from the unloading position to a third waiting position;
transferring the test tray staying at the third waiting position, from the third waiting position to a fourth waiting position; and
transferring the test tray staying at the fourth waiting position, from the fourth waiting position to the loading position.
